(19) United States
(12) Patent Application Publication
(10) Pub. No.: US 2007/0138537 A1
(43) Pub. Date: Jun. 21, 2007

(54) NON-VOLATILE MEMORY DEVICE AND METHOD OF FABRICATING A NON-VOLATILE MEMORY DEVICE

(76) Inventor: Song Hee Park, Seoul (KR)

Correspondence Address: SHERR & NOURSE, PLLC, 620 HERNDON PARKWAY, SUITE 200, HERNDON, VA, 20170, US

(21) Appl. No.: 11/609,885

(22) Filed: Dec. 12, 2006

(30) Foreign Application Priority Data
Dec. 21, 2005 (KR) 10-2005-0126702

(51) Int. Cl. H01L 29/788; H01L 21/336

(52) U.S. Cl. 257/315; 257/316; 438/257; 438/266

(57) ABSTRACT

A non-volatile memory device includes a semiconductor substrate having a plurality of trenches. A buried diffusion region may be formed in the substrate at one side of the trench. A gate insulating layer may be formed over the surface of the substrate. A floating gate may be formed over the gate insulating layer between the trenches. An insulating layer may be formed over the gate insulating layer and the floating gate. A control gate may be formed over the insulating layer.

The present application claims priority under 35 U.S.C. 119 and 35 U.S.C. 365 to Korean Patent Application No. 10-2005-0126702 (filed on Dec. 21, 2005), which is hereby incorporated by reference in its entirety.

### BACKGROUND

Non-volatile memory devices may have relatively small cells, which may have relatively fast erasing/recording capabilities and long-time data storing capacity. Non-volatile memory devices may substitute dynamic random access memory (DRAM) in products (e.g. personal digital assistants (PDA), digital cameras, personal communication systems (PCS), smart cards, and/or similar devices).

A NOR flash EEPROM may be a non-volatile memory device with a channel and source/drain junction formed as a buried diffusion region. A buried diffusion region may be doped with impurities with a high concentration (e.g, BN+ (Buried N+) region). A channel may be formed in a substrate in a region where a floating gate and a control gate are formed. Data may be stored by accelerating electrons in a BN+ region and injecting the accelerated electrons into a floating gate.

FIG. 3 is a sectional view of a non-volatile memory device. As illustrated in FIG. 3, buried diffusion region 302 (e.g. BN+ (Buried N+) region) may be formed by implanting impurity ions in high concentrations in a predetermined region of semiconductor substrate 300 (e.g. a source/drain junction). A gate insulating layer 304 may be formed over the surface of semiconductor substrate 300.

Floating gate 306 may be formed so that a part of buried diffusion region 302 overlaps with floating gate 306. Insulating layer 308 may be formed over floating gate 306 and buried diffusion region 302. Polysilicon layer 310 may be formed over insulating layer 308. Polysilicon layer 310 may be patterned and processed to form a control gate. A channel may be formed in semiconductor substrate 300 under floating gate 306 and control gate 310. Data may be stored by accelerating electrons through buried diffusion region 302 and injecting accelerated electrons into floating gate 306 through a channel.

Non-volatile memory devices may store data by accelerating electrons in buried diffusion region 302 and passing accelerated electrons into channel. A larger area for buried diffusion region 302 may result in greater acceleration of electrons in buried diffusion region 302. A greater acceleration of electrons in buried diffusion region 302 may result in better the operation speed and reliability of a memory device. In order to have a sufficient amount of electrons required for cell operation speed in a non-volatile flash memory device, buried diffusion region 302 should have an adequately large area. In highly integrated semiconductor device, there is limited area to form an adequately large buried diffusion region 302.

### SUMMARY

Embodiments relate to a non-volatile memory device and a method of fabricating a non-volatile memory device. In embodiments, a highly integrated non-volatile memory device may have reliability and adequate operation speed.

In embodiments, a non-volatile memory device comprises: a semiconductor substrate having a trench formed in the substrate; a buried diffusion region formed in the substrate on the side of the trench; a gate insulating layer formed over the substrate; a floating gate may be formed over the gate insulating layer and overlap at least a portion of the buried diffusion region; an insulating layer formed over the gate insulating layer and the floating gate; and a control gate formed over the insulating layer.

Embodiments relate to a method of fabricating a non-volatile memory device comprising: forming a trench in a semiconductor substrate; forming a buried diffusion region on the side of the trench; forming a gate insulating layer over the substrate; forming a floating gate over the gate insulating layer and overlap at least a portion of the buried diffusion region; forming an insulating layer over the gate insulating layer and the floating gate; and forming a control gate over the insulating layer.

A buried diffusion region may be formed by implanting impurity ions and then diffusing the impurity ions. Ion implantation may be performed using tilt ion implantation. A control gate may be formed along the surfaces of a trench.

### BRIEF DESCRIPTION OF THE DRAWINGS

Example FIGS. 1A through 1F are plan views illustrating fabrication of non-volatile memory devices, in accordance with embodiment.

Example FIGS. 2A through 2F are sectional views illustrating fabrication of a non-volatile memory device, in accordance with embodiments.

FIG. 3 is a sectional view of a non-volatile memory device.

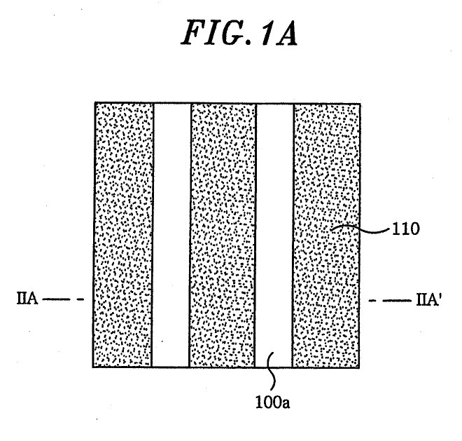

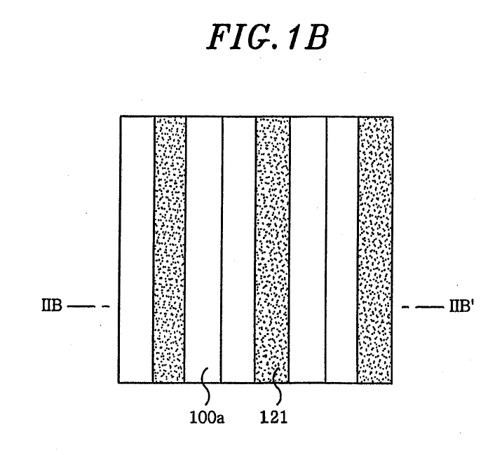

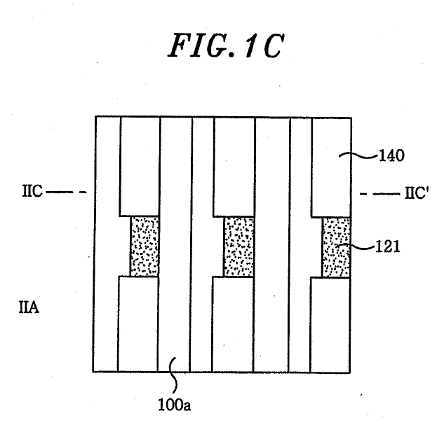

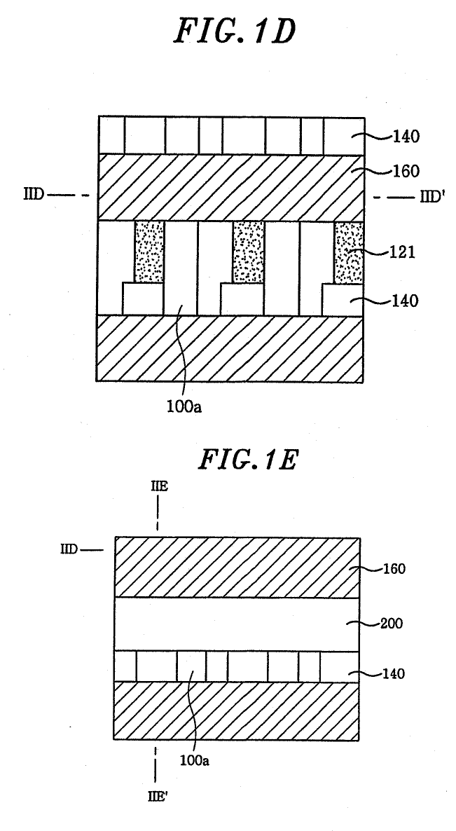

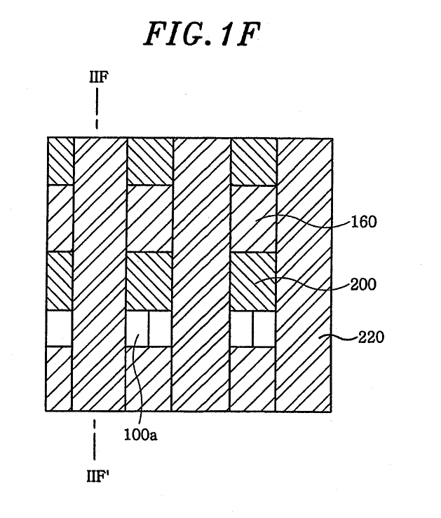

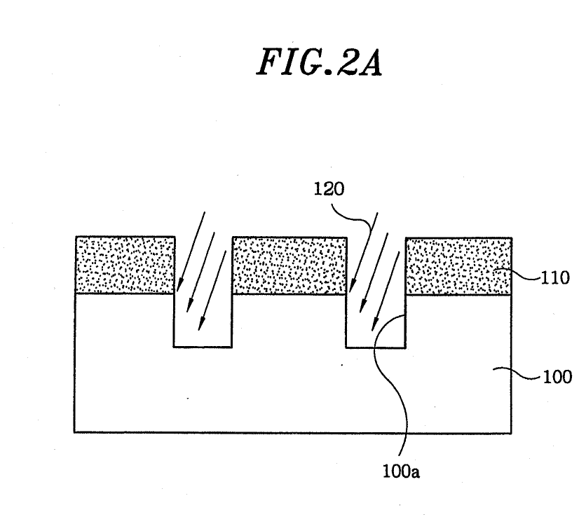

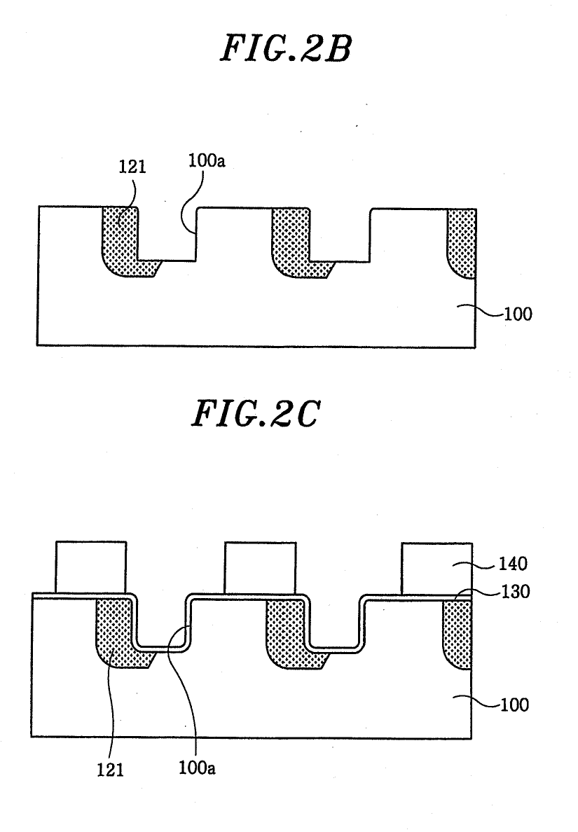

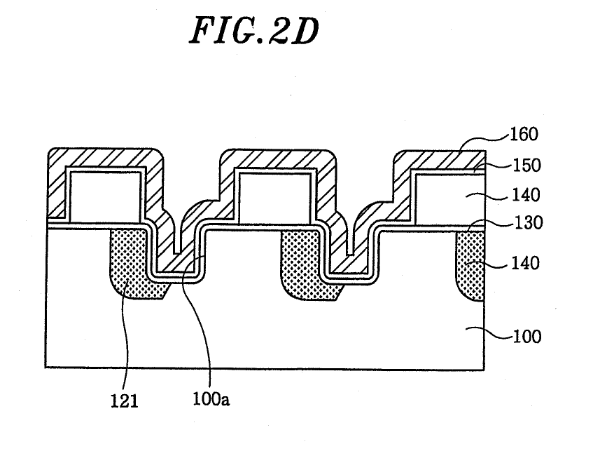

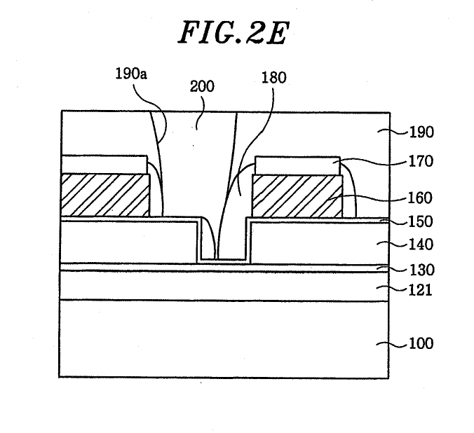

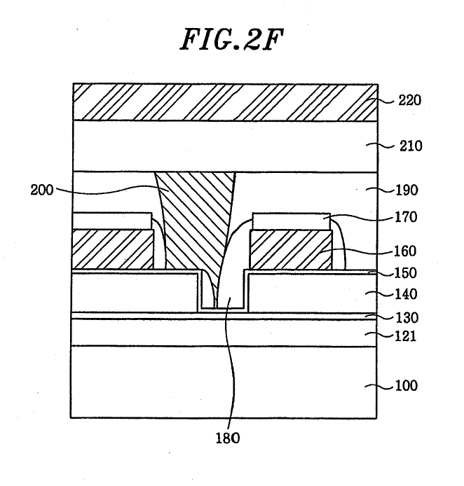

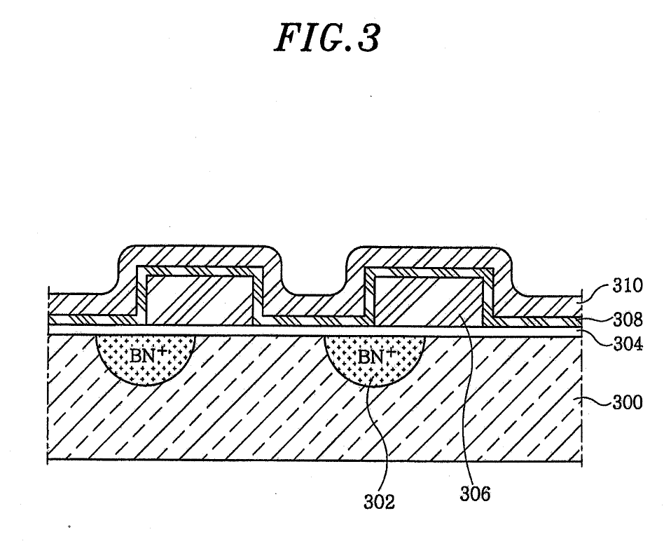

### DETAILED DESCRIPTION

FIGS. 1D to 1F and FIGS. 2D to 2F illustrate a non-volatile memory device, in accordance with embodiments. Embodiments relate to a NOR flash EEPROM device in a non-volatile memory device. FIGS. 2A through 2D are respectively sectional views taken along line IIA-IIA′ of FIG. 1A, line IIB-IIB′ of FIG. 1B, IIC-IIC′ of FIG. 1C, and IID-IID′ of FIG. D, and FIGS. 2E and 2F are respectively sectional views taken along line IIE-IIE′ of FIG. 1E and line IIF-IIF′ of FIG. 1F.

Trench 100a may be formed in a P-type semiconductor substrate 100. Buried diffusion region 121 (e.g. a BN+ region) may be formed in substrate 100 on one side of trench 100a. Gate insulating layer 130 may be formed over the surface of substrate 100 (e.g. where trench 100a is formed). Floating gate 140 may be formed over gate insulating layer 130 between trenches 100a. Insulating layer 150 may be formed over the surfaces of trenches 100a, floating gate 140, and the surface of substrate 100. Control gate 160 may be formed over insulating layer 150 and over floating gate 140. Control gate 160 may overlap floating gate 140.

An area of substrate 100 that overlaps with both floating gate 140 and control gate 160 may operate as a channel. Control gate 160 may be formed next to trench 100a above a channel. Cap oxide layer 170 may be formed over control gate 160. Spacer oxide layer 180 may be formed on a side of control gate 160.

Erase gate line 200 may be formed between neighboring control gates 160. Erase gate line 200 may be surrounded by first interlayer insulating layer 190. Second interlayer insulating layer 210 and bit line 220 may be formed over the surface of substrate 100. Gate line 200 may be arranged in the same direction as control gate 160. Bit line 220 may be arranged perpendicular to control gate 160.

In embodiments, since BN+ region 121 (which may be a data storage region) may be formed in substrate 100 at one side of trench 100a. In embodiments, even if the area of a cell is relatively small, the area of BN+ region 121 may be sufficient based on the depth of trench 100a. In embodiments, an adequate amount of electrons required to operate a cell may be obtained in a semiconductor device with a relatively high integration density.

As illustrated in FIGS. 1A and 2A, mask pattern 110 may be formed over semiconductor substrate 100. Trench 100a may be formed in substrate 100 by etching substrate 100 exposed by mask pattern 110. Substrate 100 may be etched to a thickness of about 1500 Å by an etching process using mask pattern 110 as an etch mask. Trench 100a may be formed to have a depth of about 1500 Å, in accordance with embodiments. In embodiments, depth of trench 100a may be based on the anticipated amount of electrons required for cell operation.

Semiconductor substrate 100 may be a P-type substrate or an N-type substrate with a P-well (not shown), in accordance with embodiments. N+ impurities 120 may be ion-implanted into substrate 100 on a side of trench 100a. In embodiments, ion implantation may be implemented by tilt ion implantation.

As illustrated in FIGS. 1B and 2B, impurities 120 may be diffused by annealing to form a buried diffusion region 121 (e.g. BN+ region 121) on a side of trench 100a. Mask pattern 110 may be removed.

In embodiments, after trench 100a is formed, BN+ region 121 is formed in substrate 100 by performing ion implantation on a sidewall of trench 100a. In embodiments, in a data storage operation, acceleration of electrons at BN+ region 121 is controlled, according to the depth of trench 100a. In embodiments, since BN+ region 121 is formed using trench 100a, BN+ region 121 may relatively large in a relatively small memory device cell (e.g. a highly integrated memory device may be realized).

As illustrated in FIGS. 1C and 2C, gate insulating layer 130 may be formed over the surface of substrate 100. A first polysilicon layer may be deposited over gate insulating layer 130. Floating gate 140 may be formed over substrate 100 between trenches 100a by patterning a first polysilicon layer. Gate insulating layer 130 may be formed of an oxide layer, in embodiments.

As illustrated in FIGS. 1D and 2D, insulating layer 150 may be formed over the surface of substrate 100. A second polysilicon layer may be deposited over insulating layer 150. Control gate 160 may be formed along trenches 100a, by patterning a second polysilicon layer. Insulating layer 150 may be formed over substrate 100, trenches 100a, and floating gates 140. In embodiments, insulating layer 150 may comprise at least one of an ONO layer, a nitride layer, and/or an oxide layer.

As illustrated in FIGS. 1E and 2E, cap oxide layer 170 may be formed over control gate 160. Spacer oxide layer 180 may be formed on the sidewalls of control gate 160 and cap oxide layer 170. First interlayer insulating layer 190 may be formed over the surface of substrate 100. Hole 190a may be formed in first interlayer insulating layer 190 between control gates 160 by patterning first interlayer insulating layer 190. Erase gate line 200 may be formed inside hole 190a.

As illustrated in FIGS. 1F and 2F, second interlayer insulating layer 210 may be formed over the surface of substrate 100. Bit line 220 may be formed over second interlayer insulating layer 210.

In embodiments, a non-volatile memory device may include a trench formed in a substrate with a buried diffusion region formed at the sidewall of the trench. A buried diffusion region may be formed by an ion implantation process. In accordance with embodiments, the amount of electrons required for cell operation may be obtained by controlling the depth of a trench, irrespective of a cell size, allowing for a high integration density in a memory device.

It will be apparent to those skilled in the art that various modifications and variations can be made to embodiments. Thus, it is intended that embodiments cover modifications and variations thereof within the scope of the appended claims.

What is claimed is:

1. An apparatus comprising:
a semiconductor substrate;
a trench formed in the semiconductor substrate; and
a buried diffusion region formed in the semiconductor substrate on one side of the trench.

2. The apparatus of claim 1, wherein the apparatus is a non-volatile memory device.

3. The apparatus of claim 1, comprising a gate insulating layer formed over the semiconductor substrate.

4. The apparatus of claim 3, comprising a floating gate formed over the gate insulating layer next to the trench.

5. The apparatus of claim 4, comprising an insulating layer formed over the gate insulating layer and the floating gate.

6. The apparatus of claim 5, comprising a control gate formed over the insulating layer.

7. The apparatus of claim 6, wherein the control gate is formed along the trench.

8. The apparatus of claim 1, wherein the semiconductor substrate is P-type and the buried diffusion region is N-type.

9. A method comprising:
forming a trench in a semiconductor substrate; and
forming a buried diffusion region in the semiconductor substrate on one side of the trench.

10. The method of claim 9, wherein the method comprises manufacturing a non-volatile memory device.

11. The method of claim 9, comprising forming a gate insulating layer over the semiconductor substrate.

12. The method of claim 11, comprising forming a floating gate over the gate insulating layer next to the trench.

13. The method of claim 12, comprising forming an insulating layer over the gate insulating layer and the floating gate.

14. The method of claim 13, comprising forming a control gate over the insulating layer.

15. The method of claim 14, wherein the control gate is formed along the trench.

16. The method of claim 9, wherein the buried diffusion region is formed by implanting impurity ions and diffusing the impurity ions.

17. The method of claim 16, wherein the ion implantation is performed by tilt ion implantation.

18. The method of claim 9, wherein the semiconductor substrate is P-type and the buried diffusion region is N-type.
